(19) United States
(12) Patent Application Publication
(10) Pub. No.: US 2013/0003329 A1
(43) Pub. Date: Jan. 3, 2013

(54) RUGGEDIZED HANDSET HOUSING

(75) Inventors: David PETCHEY, Atlanta, GA (US); Thomas P. VENTULETT, Mill Valley, CA (US); Jonathan A. VENTULETT, Atlanta, GA (US); Henry H. HICKS, Atlanta, GA (US); Mary E. GORMAN, Atlanta, GA (US); Brian A. TROXELL, Atlanta, GA (US)

(73) Assignee: AIRO WIRELESS, INC., Atlanta, GA (US)

(21) Appl. No.: 12/874,108

(22) Filed: Sep. 1, 2010

Related U.S. Application Data
(60) Provisional application No. 61/275,578, filed on Sep. 1, 2009.

(51) Int. Cl. H05K 7/06; H05K 13/00

(52) U.S. Cl. 361/760; 29/592.1

(57) ABSTRACT

The present invention provides an apparatus and method for providing a ruggedized handset device. A ruggedized handset device has a housing and includes a PCB, a plurality circuit components on the PCB and a conformal coatings on the plurality of circuit components to prevent a spark when the ruggedized handset device is in a volatile location. The present invention can also be viewed as providing methods for a ruggedized handset device. The method includes attaching a plurality circuit components to a PCB, providing a conformal coatings to the plurality of circuit components to prevent a spark when the ruggedized handset device is in a volatile location and attaching the PCB to the housing.

### CROSS-REFERENCE TO RELATED APPLICATION

This application claims the benefit of U.S. Provisional Patent Application entitled “Ruggedized Handset Housing”, Ser. No. 61/275,578, filed Sep. 1, 2009 which is hereby incorporated herein by reference in their entirety for all purposes.

### BACKGROUND OF THE INVENTION

1. Field of the Invention

The present invention generally relates to mobile devices, and more particularly, to a method and apparatus for a ruggedized handset device.

2. Description of Background

The application of computing technology continues to expand into ever harsher environments. At one time, computers and other computing devices were housed in separate, dedicated, climate controlled rooms. People wishing to use such machines would go to where they were located to interact with them. Considerable effort was made to cater to the environmental needs of the machines, even to the point of inconveniencing the users. Accordingly, not much concern was given to designing computers and computing devices to withstand the rigors of harsh environments.

Increasing demands on computing technology have changed all that. Today, computing devices are being deployed in ever harsher environments with one or more conditions such as volatility, liquid, waterproof, extreme temperatures, high shock, high vibration, excessive humidity, and chemical exposure. For instance, computers are commonly found in oilfield applications where they are subjected to extremes of volatility, temperature, shock and vibration. Computing technology has also found growing application in military situations, including weapons systems that are particularly high performance. Military applications, as well as some civilian applications, also add the additional pressure of life and death stakes as a function of performance level.

Much effort has therefore gone into “ruggedizing” computing technology. Sometimes this results in changes to the designs of the computing devices, connectors, buses, storage devices, etc. For instance, the design of a housing constructed to withstand higher or lower temperatures found in a particular harsh environment. Sometimes the effort results in techniques for installing an existing design. For example, an existing motherboard might be mounted in a way that helps isolate it from vibration. Cumulatively, these kinds of changes significantly impact the performance of computing technology in demanding environments.

One complicating factor is the reality that ruggedization is but one factor in the design of a computing apparatus. The engineering task usually involves a multitude of tradeoffs among competing considerations that will be implementation specific. Thus, a particular ruggedization technique may not be acceptable if it results in excessive size and weight for, e.g., a missile whereas it may be acceptable if used in, e.g., an armored ground vehicle. Thus, it is not enough that a particular ruggedization technique is available and will work, it must also not force unacceptable tradeoffs with other engineering constraints. Preferably, the ruggedization technique will actually facilitate or enhance the design's ability to meet other engineering constraints. However, even if it facilitates the design effort in multiple areas, it may still be unacceptable if it undesirably impacts the computational performance of computing apparatus.

The present invention is directed to resolving, or at least reducing, one or all of the problems mentioned above.

### SUMMARY OF THE INVENTION

Embodiments of the present invention provide a method and apparatus for a ruggedized handset device. Briefly described, in architecture, one embodiment of the system, among others, can be implemented as follows.

The apparatus includes a ruggedized handset device has a housing and includes a PCB, a plurality circuit components on the PCB and a conformal coatings on the plurality circuit components to prevent a spark when the ruggedized handset device is in a volatile location.

Embodiment of the present invention can also be viewed as providing methods for a ruggedized handset device. In this regard, one embodiment of such a method, among others, can be broadly summarized by the following steps. The method includes attaching a plurality of circuit components to a PCB, providing a conformal coatings to the plurality circuit components to prevent a spark when the ruggedized handset device is in a volatile location and attaching the PCB to the housing.

Additional features and advantages are realized through the techniques of the present invention. Other embodiments and aspects of the invention are described in detail herein and are considered a part of the claimed invention. For a better understanding of the invention with advantages and features, refer to the description and to the drawings.

### BRIEF DESCRIPTION OF THE DRAWINGS

FIG. 1 depicts a cross section view of an example of the ruggedized handset device according to an example embodiment of the present invention.

FIG. 2 depicts a cross section view of an example of the ruggedized handset device with examples of plugs and membranes that enabled the device to be watertight.

FIG. 3 is a cross section view of an example of the ruggedized handset device with examples of plugs and membranes that enabled the device to be watertight.

FIG. 4 is a cross section view of an example of the ruggedized handset device with examples.

### DETAILED DESCRIPTION OF EXAMPLE EMBODIMENTS

The present invention may be understood more readily by reference to the following detailed description of the invention taken in connection with the accompanying drawing figures, which form a part of this disclosure. It is to be understood that this invention is not limited to the specific devices, methods, conditions or parameters described and/or shown herein, and that the terminology used herein is for the purpose of describing particular embodiments by way of example only and is not intended to be limiting of the claimed invention. Also, as used in the specification including the appended claims, the singular forms “a,” “an,” and “the” include the plural, and reference to a particular numerical value includes at least that particular value, unless the context clearly dictates otherwise. Ranges may be expressed herein as from “about” or “approximately” one particular value and/or to “about” or “approximately” another particular value. When such a range is expressed, another embodiment includes from the one particular value and/or to the other particular value. Similarly, when values are expressed as approximations, by use of the antecedent “about,” it will be understood that the particular value forms another embodiment.

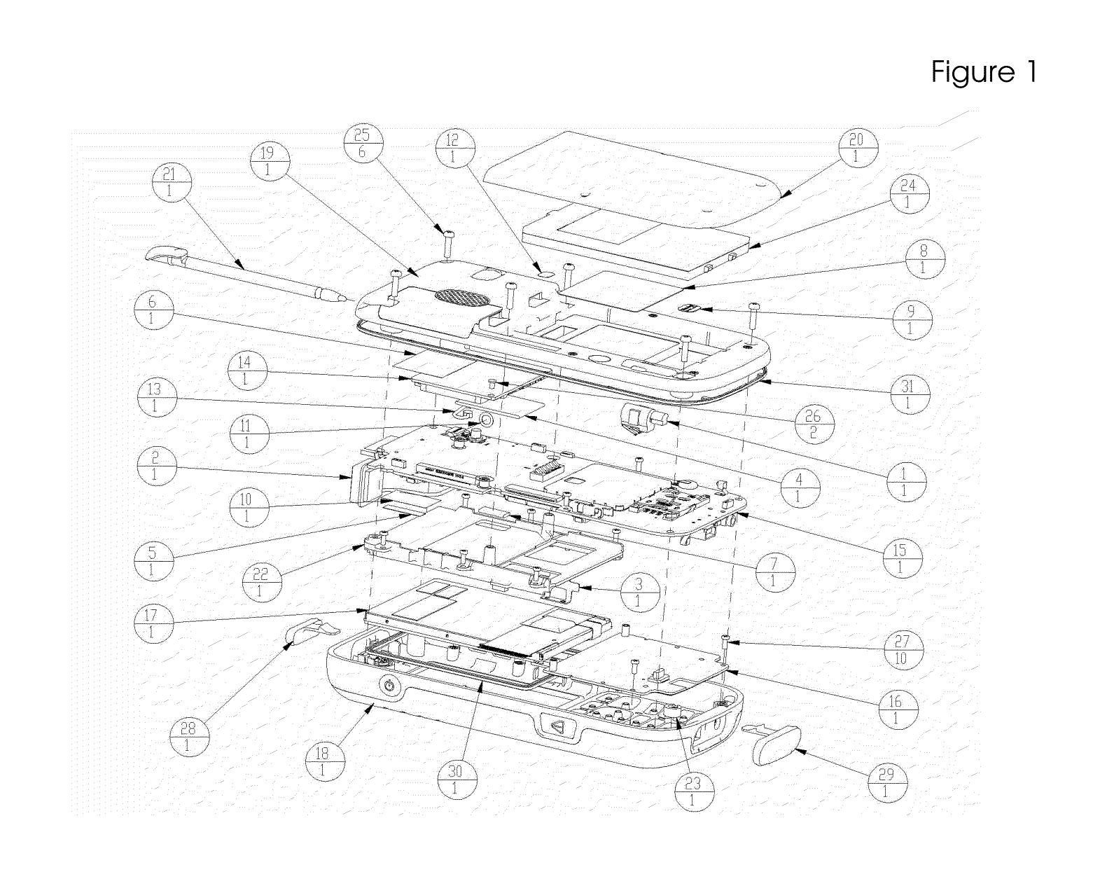

Turning now to the drawings, FIGS. 1-4 illustrate exemplary embodiment of the ruggedized handset device 10 constructed in accordance with the present invention. The ruggedized handset device 10 is sufficiently rugged to withstand elevated levels of immersion in a liquid, shock, vibration, impact, etc. and consequently be resistant to damage by crushing, deformation, breakage, disassembly from vibration, etc., found in harsh, demanding environments. To some degree, the level of ruggedness will be implementation specific. Different levels of shock and vibration will be found, for instance, on the deck of drilling rig in hydrocarbon exploration and production than will be found on the floor of a machine shop. However, various military organizations routinely specify standards with respect to these kinds of conditions that are referred to as a “military standard,” or “MIL-STD”, and MIL-STD can be referred to where applicable, even in civilian contexts, although compliance with mil specs is not necessary to the practice of the invention. For instance, standards are also set by the Underwriters Laboratory, and in particular UL 913, the Standard for Safety of Intrinsically Safe Apparatus and Associated Apparatus for use in Class I, II and III, Division 1 Hazardous Locations.

FIG. 1 depicts a cross section view of an example of the ruggedized handset device 10 according to an example embodiment of the present invention. There are a number of features of the rugged handset device tended to enable it to comply with the Standards for Safety of Intrinsically Safe Apparatus. A few of the features will be described herein below.

In one embodiment a high gain patch antenna 2/1 (FIG. 1) is included for increased satellite based derived location performance in sub-optimal environments. The increased satellite based derived location includes methods as provided by GPS, GLONAS, Galileo or the like.

In another embodiment, a spring plate 3/1 (FIG. 1) is included to add greater tactile sensation on the PTT (Push-To-Talk) function necessary for operation with gloves, as well as greater durability necessary for continual use. In an alternative embodiment, the PTT spring plate item 3/1 (FIG. 1) may include insulation characteristics as not to create a conductive connection in Intrinsically Safe environments.

In another embodiment, an electromagnetic interference (i.e. EMI) gasket 4/1 (FIG. 1) is designed to remain in place in rugged shock or impact environments. In another embodiment, EMI MMCX high-adhesive tape 5/1 (FIG. 1) is included to improve grounding necessary for operation in Intrinsically Safe designated areas whereas other methods may be subjected to failure as a result of repeated shock or impact.

In another embodiment, item 9/1 (FIG. 1) is a security label to detect unauthorized access into the handset after production to prevent tampering and thereby not compromise the inherent safety of the device.

In one embodiment is the main printed circuit board (i.e. PCB) 15/1 (FIG. 1) that is designed to provide sufficient spacing of the components on the PCB 15/1, so that dust particles of certain particulate size cannot create a circumstance where a spark can occur for protection in Intrinsically Safe environments. In another embodiment, the PCB 15/1 (FIG. 1) may have conformal coatings on components as additional levels of protection for Intrinsically Safe environments. For rugged applications, the conformal coatings are applied to enhance performance in high vibration conditions and for managing heat displacement in high temperature environments.

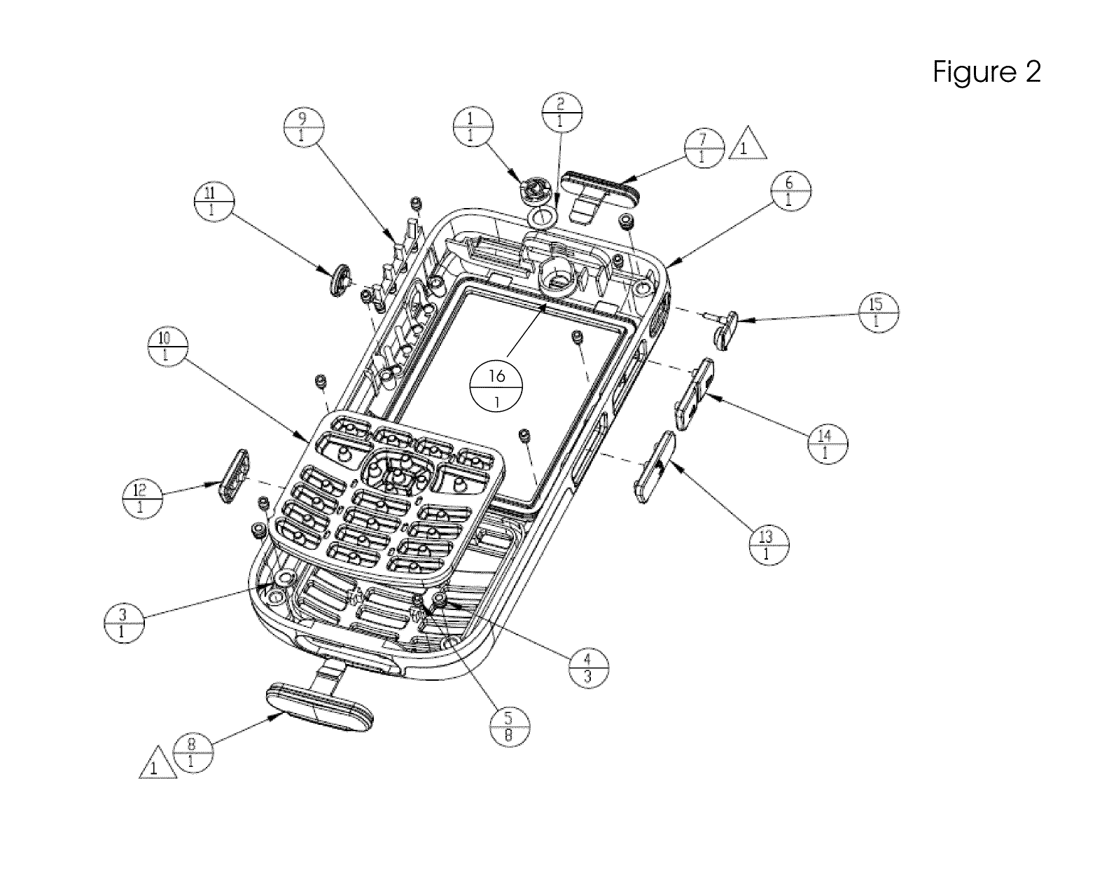

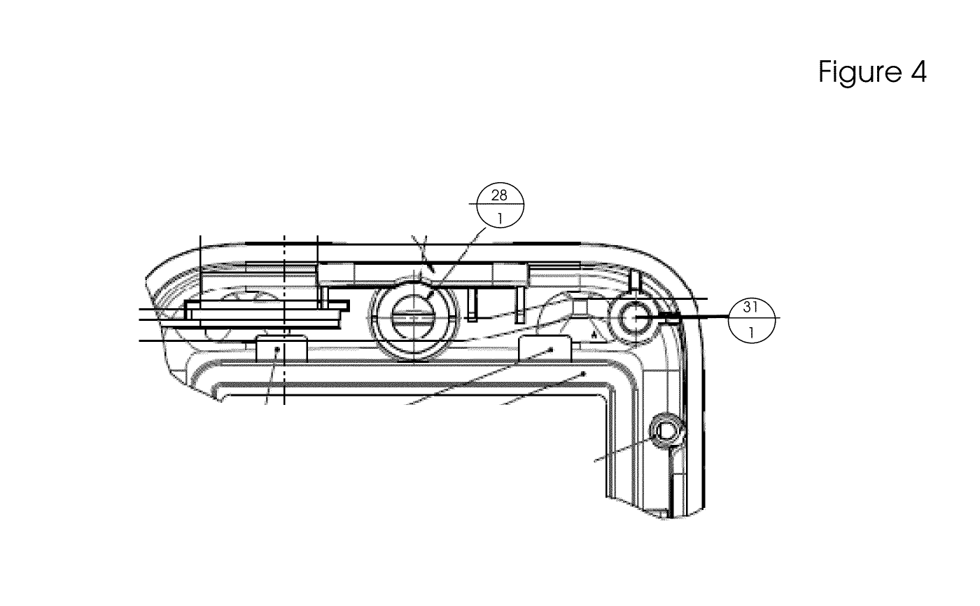

Illustrated in 16/1 (FIG. 1) is the keymat and related snap domes. The contact points of the snap dome 16/1 are sealed for rugged and Intrinsically Safe applications to prevent against dust and or particulate contamination. Item 18/1 (FIG. 1) is the front cover and is further described as FIG. 2 and FIG. 4 of this embodiment. Item 19/1 (FIG. 1) is the rear cover and is further described as FIG. 2 and FIG. 4 of this embodiment.

The battery door 20/1 utilizes a flush mounted design where a ribbed gasket 31/1 provides for a water tight seal in rugged and Intrinsically Safe applications, but allows for the entire device to functionally deform under high impact situations and return to its static form without causing a catastrophic failure in the device. A traditional method of tongue and groove interlocking parts under high impact may not allow for parts to shift or move caused by an impact event such as a drop or fall. In one embodiment, the ribbed gasket 31/1 is a double ribbed gasket or a plurality of ribs gasket. However, it is understood that the ribbed gasket 31/1 will accomplish the watertight seal with at least one rib.

In one embodiment, items 25/6 (FIG. 1) are steel fasteners for maintaining structural integrity of the device even during structural duress caused by an impact on the device. In the preferred embodiment, non-corrosive stainless steel fasteners 25/6 are utilized to provide for rugged and Intrinsically Safe applications.

The flush mounted battery door 20/1 (FIG. 1) described above coupled with the ribbed gasket 31/1, and all conjoin to enabling parts to shift, but without adversely impacting the integrity of the entire design of the ruggedized handset device 10.

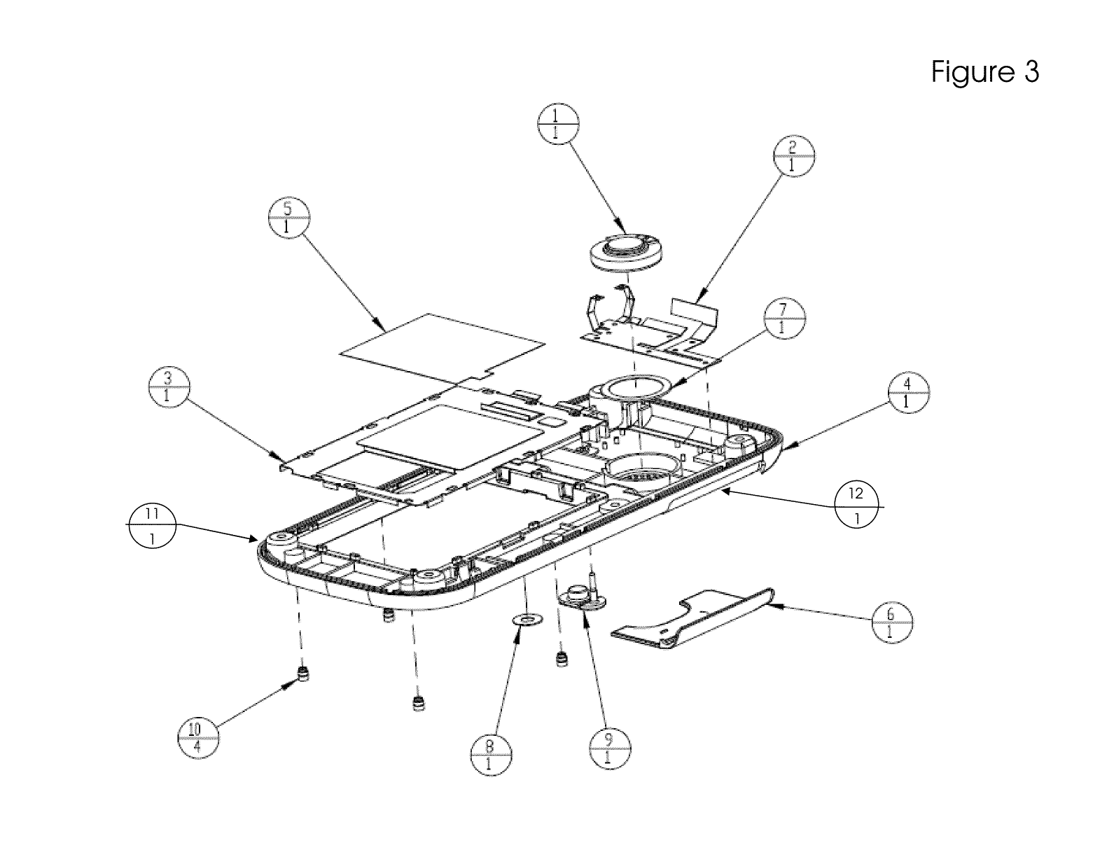

Illustrated in FIG. 1 is the stylus 21/1 and relating stylus cavity door 6/1 (FIG. 3). The stylus cavity for rugged and Intrinsically Safe applications is an independent channel (not shown) for storing the stylus 21/1 while fully separate from the interior of the ruggedized handset device 10.

Also Illustrated in FIG. 1 is the display frame 22/1. This frame 22/1 serves multiple purposes in rugged and Intrinsically Safe applications. In the preferred embodiment, the frame 22/1 is constructed from magnesium, however it is understood that other lightweight non-ferrous metals may be utilized. The display frame 22/1 protects the display 17/1 from twist and torque loads that may crack or destroy the display 17/1 by isolating stress around and away from the display 17/1. Further the display frame 22/1 applies the appropriate and necessary pressure between the front cover 18/1 and the display gasket 30/1 to ensure a water tight seal without applying such pressure as to alter the performance of the touch screen display 17/1.

Also illustrated in FIG. 1, is a marine rated microphone 23/1 that is permanently sealed and glued into a cast cavity for rugged and Intrinsically Safe applications. A hydrophobic membrane 3/1 (FIG. 2) provide a liquid barrier between the receiver and the opening to the outside of the rugged handset device 10 to provide for rugged and Intrinsically Safe applications. In an alternative embodiment, the hydrophobic membrane 3/1 (FIG. 2) is also oleophobic. This hydrophobic membrane 3/1 is preferably adhered, glued or the like into place independently from the microphone 23/1 (FIG. 1), to obtain a dust proof (dust of any particulate size) and water tight (a depth of 1 meter of water for at least 30 minutes) integrity and to preserve audio quality in the microphone 23/1 (FIG. 1). In an alternative embodiment other types of microphones could be utilized as long as they are shielded from water, dust, and grass.

Illustrated in FIG. 1 is a lithium-ion battery 24/1 that is specified to meet power and chemistry limitations associated with Intrinsically Safe applications. However, it is understood that any battery of sufficient power may be utilized.

Also illustrated in FIG. 1, are non-corrosive stainless steel fasteners 26/2 and 27/10 and accompanying nut inserts 4/3 (FIG. 2) are for rugged and Intrinsically Safe applications that independently secure the main PCB 15/1 (FIG. 1) and the keymat 16/1 with a minimum spacing of at least 1 mm from the interior edge of the front cover shown as part 18/1 in FIG. 1. In the preferred embodiment, main PCB 15/1 and keymat 16/1 (FIG. 1) are anchored in place and further secured by insulating bushings isolate critical components from the transfer of impact energy, torque, twist or other destructive force that could damage or impair the performance of such critical components. Nut inserts 4/3 (FIG. 2) are placed into cast holes that are offset from the edge of the device and have double reinforcement as shown at location 31 in FIG. 4. The GPS patch antenna part 2/1 (FIG. 1) is secured in place in a cast slot with at least 1 mm minimum perimeter spacing as applied to the main PCB 15/1 and keymat 16/1 in FIG. 1.

In one alternative embodiment, a vibration motor 1/1 (FIG. 1) of sufficient strength for user notifications in environments not conducive to audible notifications. The vibration motor is of brush-less design so as not to create a spark, or as to be compliant with necessary certifications in an Intrinsically Safe environment.

Illustrated in FIG. 1 is the front cover 18/1 which is also shown as front cover 6/1 in FIG. 2 is cast from Lexan® or the like material with a wall thickness of no less than 2 mm. Front cover 18/1 (FIG. 1) or 6/1 (FIG. 2) in one embodiment includes rounded corners, internal support ribbing, and raised reinforcement around openings all to improve the structural integrity of the cover.

Illustrated in FIG. 2 is a marine rated receiver 1/1 that is permanently sealed and glued into a cast cavity 16/1 (FIG. 2) for rugged and Intrinsically Safe applications. A hydrophobic membrane 2/1 (FIG. 2) provide a liquid barrier between the marine rated receiver 1/1 and the opening to the outside of the rugged handset device 10 to provide for rugged and Intrinsically Safe applications. In an alternative embodiment, the hydrophobic membrane 2/1 (FIG. 2) is also oleophobic. This membrane 2/1 is preferably adhered, glued or the like into place independently from the receiver 1/1 (FIG. 2), to obtain a dust proof (dust of any particulate size) and water tight (a depth of 1 meter of water for at least 30 minutes) integrity and to preserve audio quality in the receiver.

Illustrated in FIG. 2 as Parts 7/1 and 8/1 and also shown as parts 28/1 and 29/1 (FIG. 1), are the mini-SD and USB, audio, and system reset ports respectively. In the preferred embodiment, these plugs are V1 or V0 rated rubber parts to remain heat resistant or fire retardant as needed for rugged or Intrinsically Safe applications. In one embodiment, these plugs 28/1 and 29/1 (FIG. 1) and 7/1 and 8/1 (FIG. 2), have at least one micro rib to prevent against water and dust ingress when secured in place. In the preferred embodiment, plugs 28/1 and 29/1 (FIG. 1) and Parts 7/1 and 8/1 (FIG. 2), have multiple micro-ribs to prevent water and dust ingress.

Illustrated in FIG. 2 is an alternative embodiment of a light pipe 9/1 that conveys system status information visible to the user on the surface of the device while keeping LED elements (not shown) at a distance from the surface of the ruggedized handset device 10 where they can be damaged or the compromised.

Illustrated in FIG. 2 is the keypad 10/1 that is preferably designated as a V1 or V0 rated silicon material so as to maintain a non-conductive interface with the user as further described in FIG. 2. However, it is contemplated by the inventors that other nonconductive materials may be utilized for keypad 10/1.

Also illustrated in FIG. 2 is a power button 11/1 that is preferably designated as a V1 or V0 rated rubber material so as to maintain a non-conductive interface with the user. However, it is contemplated by the inventors that other nonconductive materials may be utilized for power button 11/1.

Illustrated in FIG. 2 is an emergency function button 12/1, a PTT button 13/1, 14/1 in FIG. 2 is a volume button 14/1, an external GPS antenna port 15/1 and 9/1 (FIG. 3). Preferably, all or most of these components are V1 or V0 rated rubber components to remain heat resistant or fire retardant in rugged or Intrinsically Safe applications. Preferably, all of these components come with multiple ribbed features to ensure that openings remain dust proof (dust of any particulate size) and water tight (a depth of 1 meter of water for at least 30 minutes). However, in alternative embodiments, these components come with at least one rib feature.

Illustrated in FIG. 3 is the rear cover 4/3 which is also shown as rear cover 19/1 in FIG. 1, is cast from Lexan® or the like material with a wall thickness of no less than 2 mm. Rear cover 19/1 (FIG. 1) or 4/3 (FIG. 3) in one embodiment includes rounded corners, internal support ribbing, and raised reinforcement around openings all to improve the structural integrity of the cover. The rear cover 19/1 (FIG. 1) or 4/3 (FIG. 3) has a slot 11/1 (FIG. 3) to support the main gasket 31/1 (FIG. 1). This main gasket 31/1 (FIG. 1) is used in conjunction with the flush mount flat face of the front cover 18/1 (FIGS. 1) and 6/1 (FIG. 2), and secured by main screws 25/6 (FIG. 1) to create a dust and water tight seal while allowing the rugged handset device 10 to flex, shift, move, torque or otherwise distort during an impact and return without a catastrophic or destructive effect on the device retaining its integrity in rugged or Intrinsically Safe applications.

Also illustrated in FIG. 3, is a speaker 1/1 (FIG. 3) that is permanently sealed into a cast cavity 12/1 (FIG. 3) for rugged and Intrinsically Safe applications. In the preferred embodiment, a marine rated speaker 1/1 (FIG. 3) is permanently sealed into cavity 12/1 (FIG. 3). However, it is understood that other types of temporary sealing of the marine rated speaker 1/1 (FIG. 3) into the steel cavity 12/1 (FIG. 3), could be sufficient. A hydrophobic membrane 7/1 (FIG. 3) provide a liquid barrier between the speaker 1/1 and the opening to the outside of the rugged handset device 10 to provide for rugged and Intrinsically Safe applications. In an alternative embodiment, the hydrophobic membrane 7/1 (FIG. 3) is also oleophobic. This membrane 7/1 is preferably adhered, glued or the like into place independently from the speaker 1/1 (FIG. 3), to obtain a dust proof (dust of any particulate size) and water tight (a depth of 1 meter of water for at least 30 minutes) integrity and to preserve audio quality of the speaker.

Illustrated in FIG. 3 is a stamped metal battery frame 3/1 to ensure that the battery 24/1 is encased in a stable frame. The stamped metal battery frame 3/1 (FIG. 3) is to prevent against shifting or other movement against a compression battery connector in a rugged or Intrinsically Safe application.

Also illustrated in FIG. 3, is a non-conductive shielding 5/1 that separates components on the main PCB 15/1 (FIG. 1) from the metallic battery frame 3/1 (FIG. 3).

Illustrated in FIG. 3 is an alternative embodiment that provides a air vent 8/1 that is an oleophobic and hydrophobic membrane that may be incorporated in devices for rugged and Intrinsically Safe applications where excessive humidity might be introduced during charging, SIM card replacement or extreme air pressure changes might occur justifying additional uni-permeable ports for returning the ruggedized handset device 10 to an acceptable stabilized condition necessary for operation in rugged or Intrinsically Safe applications.

Illustrated in FIG. 4 are cast holes that are offset from the edge of the ruggedized handset device 10 and have double reinforcement as shown at location 31.

While the invention has been shown and described in preferred forms, it will be apparent to those skilled in the art that many modifications, additions, and deletions can be made therein. These and other changes can be made without departing from the spirit and scope of the invention as set forth in the following claims.

1. A ruggedized handset device having a housing, the ruggedized handset device comprising:
a PCB;
a plurality of circuit components on the PCB; and
a conformal coatings on the plurality circuit components to prevent a spark when the ruggedized handset device is in a volatile location.

2. The ruggedized handset device of claim 1, further comprising:
at least one non-conductive spring plate behind high use buttons, sufficient spacing around numeric keys, and high tactile resistance for improved user experience.

3. The ruggedized handset device of claim 1, wherein the plurality circuit components have a minimum spacing between the plurality circuit components on the PCB.

4. The ruggedized handset device of claim 1, wherein the PCB has a minimum spacing between the PCB and the housing.

5. The ruggedized handset device of claim 1, further comprising:
a front cover;
a rear cover;
a battery door;
and wherein each covers and the door are joined together with a flush mount side and a ribbed gasket side which allows for the entire device to functionally deform under high impact situations and return to its static form without causing a failure in the ruggedized handset device.

6. The ruggedized handset device of claim 1, further comprising:
a display frame that protects a display while applying sufficient pressure as to create a water tight seal.

7. The ruggedized handset device of claim 1, further comprising:
a receiver: and
a hydrophobic membrane that provides a liquid barrier between the receiver and the opening to the outside of the ruggedized handset device to protect the ruggedized handset device from liquids.

8. The ruggedized handset device of claim 7, wherein the hydrophobic membrane is adhered to the ruggedized handset device in a place independently from the receiver to preserve audio quality in the receiver.

9. The device of claim 7, wherein the hydrophobic membrane is oleophobic.

10. The ruggedized handset device of claim 1, further comprising:
insulated bushings between the PCB and the housing.

11. The ruggedized handset device of claim 10, wherein the insulated bushings isolate the plurality circuit components from the transfer of impact energy applied to the housing that could impair the performance of the plurality circuit components on the PCB.

12. A method for creating a ruggedized handset device having a housing, comprising:
attaching a plurality of circuit components to a PCB;
providing a conformal coatings to the plurality circuit components to prevent a spark when the ruggedized handset device is in a volatile location;
and attaching the PCB to the housing.

13. The method of claim 12, wherein the plurality circuit components have a minimum spacing between the plurality circuit components on the PCB.

14. The method of claim 12, wherein the PCB has a minimum spacing between the PCB and the housing.

15. The method of claim 12, wherein the ruggedized handset device, further comprises:
a front cover;
a rear cover;
a battery door; and
joined each covers and the door are together with a flush mount side and a ribbed gasket side which allows for the entire device to functionally deform under high impact situations and return to its static form without causing a failure in the ruggedized handset device.

16. The method of claim 12, further comprising:
protecting a display with a display frame that applies sufficient pressure as to create a water tight seal.

17. The method of claim 12, further comprising:
inserting a hydrophobic membrane between a receiver and an opening to the outside of the ruggedized handset device to protect the ruggedized handset device from liquids.

18. The method of claim 12, wherein the hydrophobic membrane is oleophobic.

19. The method of claim 12, further comprising:
insulated bushings between the PCB and the housing.

20. The method of claim 19, wherein the insulated bushings isolate the plurality circuit components from the transfer of impact energy applied to the housing that could impair the performance of the plurality circuit components on the PCB.
